(19) United States
(12) Patent Application Publication
(10) Pub. No.: US 2007/0130490 A1
(43) Pub. Date: Jun. 7, 2007

(54) Information protection using properties of a printed electronic circuit

(76) Inventors: Shmuel Silverman, Buffalo Grove, IL (US); Timothy J. Collins, Homer Glen, IL (US); Robert A. Perri, Bartlett, IL (US)

Correspondence Address: MOTOROLA, INC., 1303 EAST ALGONQUIN ROAD, IL01/3RD, SCHAUMBURG, IL, 60196, US

(21) Appl. No.: 11/294,137

(22) Filed: Dec. 2, 2005

(51) Int. Cl. H01R 9/00; G01R 31/28; H03M 13/00; G01R 31/04; H05K 5/00

(52) U.S. Cl. 714/734; 361/679; 324/538; 714/781

(57) ABSTRACT

Apparatus and methods for manufacturing and reading the apparatus is disclosed. The apparatus includes: a storage medium (610) comprising a first material; and a printed electronic circuit (104) coupled to the storage medium, the printed electronic circuit comprising a first portion (206) that includes a plurality of printed electronic circuit elements that generate a secret code, wherein the secret code is based on an electronic characteristic of each circuit element as randomly set by a parameter of at least one semiconductor ink used to generate the printed electronic circuit.

### CROSS-REFERENCE TO RELATED APPLICATIONS

The present application is related to the following U.S. application commonly owned together with this application by Motorola, Inc.:

Ser. No. ______, filed Dec. 2, 2005, titled “Information Protection Using a Printed Electronic Circuit and Mechanical Impression” by Silverman, et al. (attorney docket no. CM09013G); and

Ser. No. ______, filed Dec. 2, 2005, titled “Information Protection Using a Printed Electronic Circuit and Laser Impression” by Silverman, et al. (attorney docket no. CM09014G).

### FIELD OF THE INVENTION

The present invention relates generally to information security and more particularly to techniques and apparatus to secure information contained on a storage medium using a printed electronic circuit that is coupled to the storage medium.

### BACKGROUND OF THE INVENTION

Many types of information such as executable code (software), audio, video, etc. are stored in various types of storage media and sold as products for profit. This includes such items as music stored on audio Compact Disc (CD), movies stored on DVD and Video CD, computer software stored on CD Read-Only Memory (CD-ROM), etc. Naturally, to maximize potential profit, sellers of such products stored on storage media desire copy protection (also known as copy prevention and copy control) of their product, which is defined herein as any technical measure designed to prevent unauthorized duplication of the information stored on the storage medium.

The existing techniques used to secure such media have proven ineffective. For example, more recently publishers of music and movies in digital form have turned to encryption to make copying more difficult. Content Scrambling System (CSS) encryption, which is used on DVDs, is one example. Using this encryption method, the information on the DVD is encrypted using a 40-bit encryption key. The key is only included on the original DVD copy and in the firmware of “authorized” players. The key included on the original DVD copy is not writable on DVD-R or DVD-RW discs, which is designed to render copies unplayable since the copies will be missing the key. However, CSS (and other such software-based solutions) have been reverse engineered, thereby, providing access to the encryption keys and methods.

Thus, there exists a need for more robust techniques and apparatus for securing information stored on storage media.

### BRIEF DESCRIPTION OF THE DRAWINGS

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 illustrates reader and tag apparatus in accordance with an embodiment of the present invention;

FIG. 2 illustrates a block diagram of a printed electronic circuit comprising the tag shown in FIG. 1;

FIG. 3 illustrates a printed transistor memory array included in the printed electronic circuit shown in FIG. 2;

FIG. 4 illustrates a modulation circuit included in the printed electronic circuit shown in FIG. 2;

FIG. 5 illustrates a disc storage medium that includes the tag shown FIG. 1 and a reader for the disc storage medium that includes the reader shown in FIG. 1 in accordance with an embodiment of the present invention;

FIG. 6 illustrates a flow diagram of a method in accordance with an embodiment of the present invention for manufacturing the storage medium and printed electronic device shown in FIG. 5;

FIG. 7 illustrates a flow diagram of a method in accordance with another embodiment of the present invention for manufacturing the storage medium and printed electronic device shown in FIG. 5; and

FIG. 8 illustrates a flow diagram of a method in accordance with another embodiment of the present invention for manufacturing the storage medium and printed electronic device shown in FIG. 5.

### DETAILED DESCRIPTION OF THE INVENTION

Before describing in detail embodiments that are in accordance with the present invention, it should be observed that the embodiments reside primarily in combinations of method steps and apparatus components related to a method and apparatus for information protection using a printed electronic circuit. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein. Thus, it will be appreciated that for simplicity and clarity of illustration, common and well-understood elements that are useful or necessary in a commercially feasible embodiment may not be depicted in order to facilitate a less obstructed view of these various embodiments.

Generally speaking, pursuant to the various embodiments, techniques and apparatus utilizing printed electronic circuit technology is implemented to secure information stored on storage media. In one embodiment, an impression is generated on a storage medium and a printed electronic circuit is coupled to the storage medium such that a first portion of the circuit is positioned adjacent to the impression for causing the impression to alter the first portion to generate a secret code. In another embodiment, a printed electronic circuit is coupled to a storage medium and an impression is cut into a first portion of the circuit to alter the first portion to generate a secret code. In yet another embodiment, a printed electronic circuit is coupled to a storage medium, the printed electronic circuit comprising a first portion that includes a plurality of printed electronic circuit elements that generate a secret code, wherein the secret code is based on an electronic characteristic of each circuit element as set by a parameter of at least one semiconductor ink used to print the circuit elements.

These embodiments provide advantages over the existing technology by providing a superior means of protecting the secret code from being discovered by unauthorized users and thereby protecting the information stored on the disk from being copied by an unauthorized user. Those skilled in the art will realize that the above recognized advantages and other advantages described herein are merely exemplary and are not meant to be a complete rendering of all of the advantages of the various embodiments of the present invention.

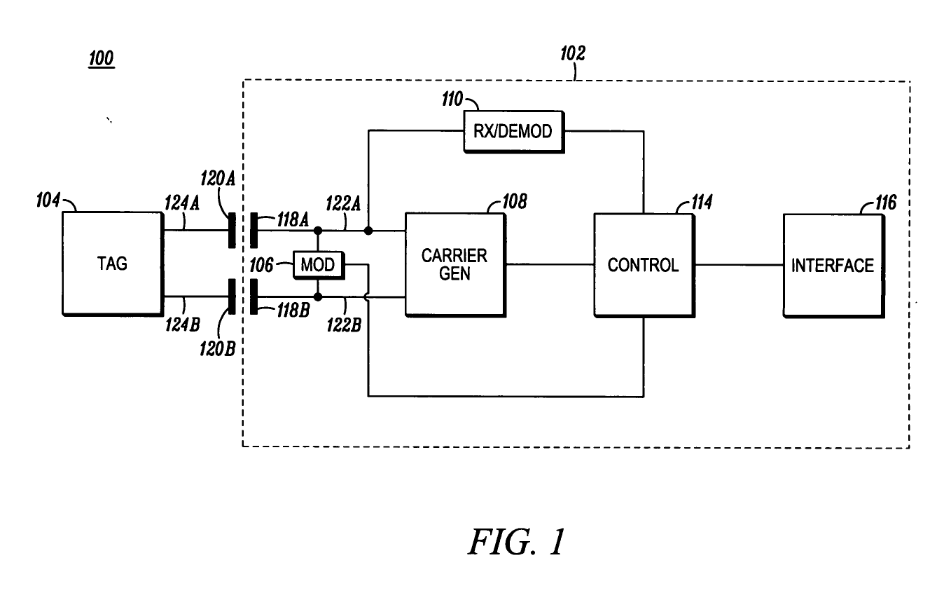

Referring now to the drawings, and in particular FIG. 1, apparatus in accordance with an embodiment of the present invention is shown and indicated generally at 100. Apparatus 100 comprises a destination device (also referred to herein as a reader) 102 for reading a storage medium (not shown), such as a disc storage medium, and a source device (also referred to herein as a tag) 104 comprising a printed electronic circuit that is coupled to the disc storage medium and to the reader 102 in accordance with embodiments described in more detail by reference to the remaining figures. The disc may comprises a CD, CD-ROM, DVD, etc., for storing a variety of different information including, but not limited to, movies, music, software, etc. A printed electronic circuit is defined herein as an electronic circuit comprising a plurality of electronic elements that are printed with various printed techniques using functional inks such as, conductive ink, semiconductor ink, etc.

Those skilled in the art, however, will recognize and appreciate that the specifics of this illustrative example are not specifics of the invention itself and that the teachings set forth herein are applicable in a variety of alternative settings. For example, since the teachings described do not depend on the storage medium or the type of information stored thereon, they can be applied to any type of storage medium although a disc storage medium is shown in this embodiment. As such, other alternative implementations of using different types of storage medium are contemplated and are within the scope of the various teachings described such as, for instance, any storage medium that can have an impression generated within it and can have a printed electronic circuit coupled thereto.

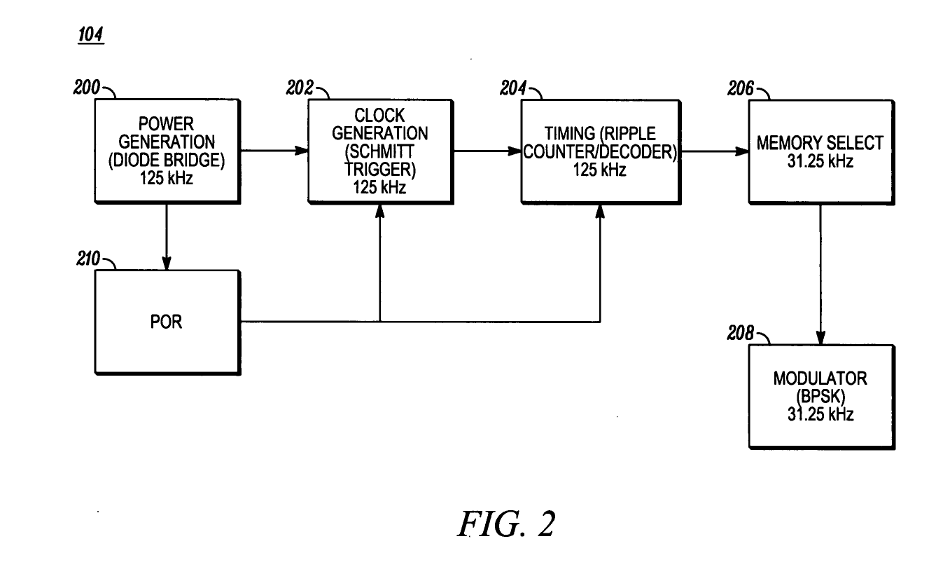

In the embodiment illustrated by reference to FIG. 1, system 100 is implemented as an electrostatically coupled system with reader 102 being a radio frequency identification (RFID) reader and tag 104 being an RFID tag. RFID tag 104 comprises the printed electronic circuit as described below in detail by reference to FIGS. 2-5, which includes an antenna 120 (having antenna elements 120a and 120b that may be plates or wires). RFID reader 102 comprises a carrier generation circuit 108, an antenna 118 (having antenna elements 118a and 118b that may be plates or wires) used to capacitively couple a carrier signal developed in the carrier generation circuit 108, a modulator circuit 106 used to send command data to RFID tag 104, a receiver/demodulation circuit 110 used to decode data sent by tag 104, an access interface circuit 116 and a control circuit 114. In general, modulator circuit 106 is coupled to control circuit 114 and access interface circuit 116 to generate and send command code signals to RFID tag 104. In one embodiment, the signals transmitted to RFID tag 104 are wireless radio frequency signals, permitting a wireless and contactless interface between RFID tag 104 and RFID reader 102. This contactless interface may include electrostatic, electromagnetic, far field or any other wireless coupling mechanisms. In one embodiment, electrostatic coupling is used whereby plates 120a, 118a and 120b and 118b make up the coupling mechanism between tag 104 and reader 102. Alternatively coupling between RFID tag 104 and RFID reader 102 may require physical and direct contact or connection whereby an electrical connection is made between RFID reader 102 and RFID tag 104 at nodes 122a, 124a and 122b and 124b respectively.

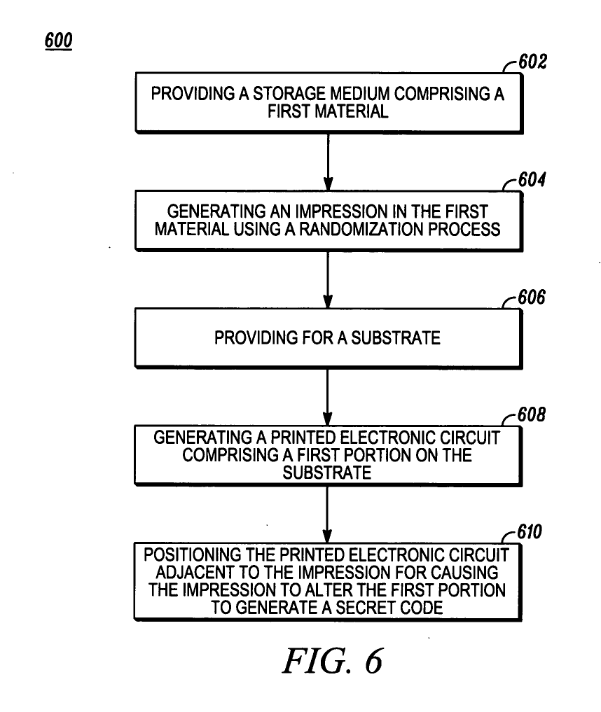

FIG. 2 is a block diagram of RFID tag 104 implemented in a passive configuration. In this passive configuration, tag 104 receives power from signals received from the reader device. However, those of ordinary skill in the art will realize that the tag may alternatively have an internal power source such as a suitable battery. Tag 104 comprises a power generation circuit 200 that is used to convert the carrier signal (generated by RFID reader 102) into a direct current (DC) power to be consumed by RFID tag 104. In one embodiment, to keep power consumption low and minimize the number of components on RFID tag 104, clock generation is developed from the carrier signal generated by RFID reader 102 through a circuit 202, such as Schmitt trigger circuit, included on RFID tag 104 and that is well known in the art. Command sequencing/timing 204 is developed through a simple ripple counter configuration. RFID tag 104 further includes a memory select circuit 206 for storing a secret code that can be generated using any one of the processes described below by reference to FIGS. 6-8. This secret code can be sent to the reader using a modulation circuit 208. Power on reset (POR) circuit 210 is used to reset circuit 208 prior to transmission of data to reader 102 and after the power level to the tag has reached a predetermined level

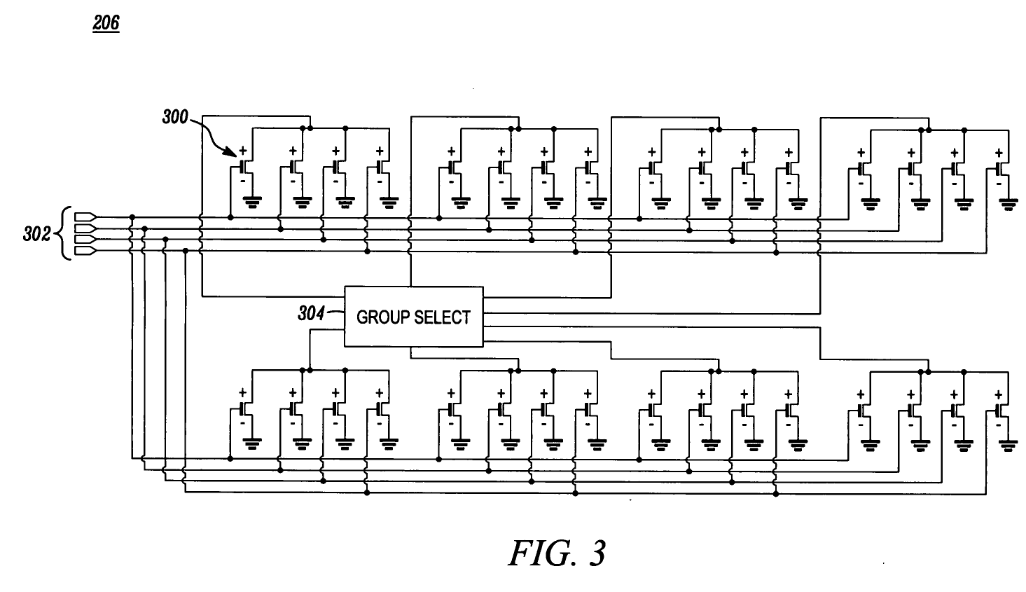

Printed transistors as described in more detail below have a unique characteristic in that the portions (e.g. active, gate/drain/source metal or dielectric) of the transistor can be easily deposited, not deposited or removed at the point of manufacture. It should also be noted that the amount of the materials which make up the drain, source, gate, dielectric or active can also be varied allowing for the transistor characteristic to vary. This method of manufacture allows for much flexibility in the development of printed memory devices. FIG. 3 illustrates an embodiment of a printed memory for RFID tag 104 in accordance with the present invention. The printed memory array comprises a plurality of printed transistors such as a pull down transistor 300. The output of the timing circuit 204 is coupled to memory 206 through lines 302. The contents of memory 206 will vary in accordance with the various processes (e.g., 600, 700, 800) used to generate the memory array.

Memory 206 in this embodiment is designed in a read only memory (ROM) type structure with transistors grouped in blocks of four bits. Pull down transistor 300 can be thought of as the memory bit and is used to set the “0” or “1” state of the memory output for each bit. The gate voltage for transistor 300 is coupled to timing circuit 204. The voltages seen on the gate of pull down transistor 300 will vary in sequential pattern in accordance with the variation in the state of circuit 204, allowing each bit to be uniquely selected within each 4 bit block of memory 206. The source side of pull down transistor 300 is controlled by group select logic 304. The voltage seen on the source side of transistor 300 is coupled to the memory's sense amplifier (not shown). The group select logic outputs will also vary in a sequential pattern allowing each block of 4 memory bits to be uniquely selected. As mentioned earlier the ability to deposit, not deposit or remove the materials which make up the transistor allow for transistor 300 to act as a pull down, if all transistor materials are present in the amounts and locations required for this function or transistor 300 may not function as a pull down transistor if some or all of the transistor materials/characteristics have been modified so that transistor 300 can not act as a transistor.

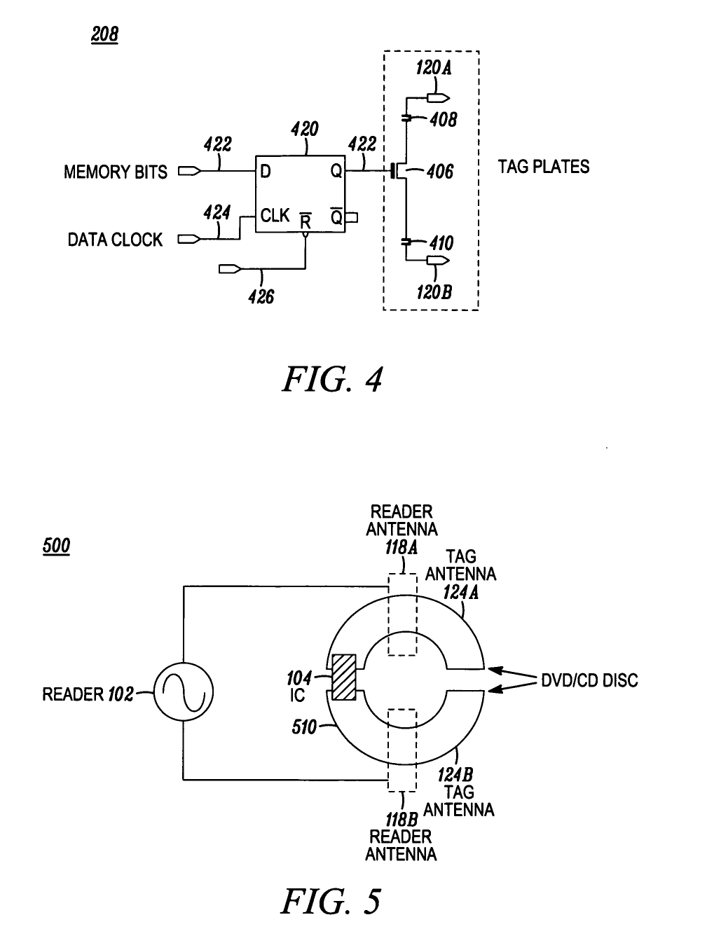

FIG. 4 is the modulator circuit 208 for RFID tag 104. In one embodiment, the source side of memory transistor 300 is coupled to the D input (422) of a flip flop 420 comprising modulator 208. Flip flop 420 and a clock input 424 from clock generation block 202 is coupled to timing/sequencer circuit 204 and is used to properly synchronize tag data to be transmitted to RFID reader 102. A Q output 412 of flip flop 420 is used to drive a gate of a modulation device 406. In operation, as RFID reader 102 varies the amplitude of the carrier signal presented to RFID tag 104 the voltage seen on plates 120a and 120b will vary causing the vgs (gate to Source Voltage) for transistor 406 to vary. Amplitude modulation is created by allowing the vgs for transistor 406 to exceed a threshold for device 406 allowing capacitors 408 and 410 to act as load devices shunting the carrier signal seen by reader 102.

FIG. 5 is a schematic of the RFID reader 102 and RFID tag 104 in an embodiment wherein the tag is coupled to a disc storage medium and the RFID reader comprises a disc reader. The RFID tag antenna plates 120a and 120b can be printed onto the disc or can be comprised of the disc material. For example, the antenna plates may comprise metal that is sandwiched between and comprises the disc material. Electrostatic coupling occurs when the reader antenna plates 118a and 118b are coupled to the tag antenna plates 120a, 120b. Plates 118a, 118b, 120a and 120b comprise any conductive material. Moreover, tag 104 circuitry can be manufactured using traditional semiconductor material, printed semiconductor material or a combination of printed and traditional, as described in detail below.

Turning now to FIG. 6, a flow diagram of a manufacturing method for producing a storage medium with a printed electronic circuit in accordance with an embodiment of the present invention is shown and generally indicated at 600. In a step 602, a storage medium comprising a first material is provided for. The storage medium is any suitable storage medium such as a storage disc as described above. In the case of a storage disc, the first material comprising the disc may be, for instance, a metallized plastic as is well known in the art. The storage medium may store various information, as described above, which is encoded or etched onto the disc during a manufacturing process. In one exemplary manufacturing process the disc is “pressed” using a suitable pressing tool as is well known in the art for etching the information onto the disc. Such a process enables mass production of discs containing the information. In an alternative embodiment the information may be recorded to one disc at a time.

In a step 604, an impression is generated in the material of the disc using a randomization process. In one embodiment, the impression is carved into the material of the disc using a tool that is different from the pressing tool used to press the information on the disc. The randomized process used to generate the impression may be the result of a number of factors. One factor may be the tool used to manufacture the disc in that, for example, it may spin the disc to a random disc orientation prior to the impression being generated in the material. Another factor may be that the tool used to generate the impression implements an algorithm that randomizes, for example: the location on the disc of the impression including how the impression is oriented with respect to the disc orientation; and a pattern of the impression including the physical dimensions of the impression and a design of the impression.

In a step 606, a substrate for the printed electronic circuit is provided for. The substrate may be comprised of the material that is used to make the storage medium in an embodiment where the printed electronic circuit is printed directly onto the disc material. Alternatively the substrate may be comprised of a different material than the disc. In one embodiment, the substrate material comprises a flexible substrate comprised, for example, of polyester, paper, plastic, acetate, polyethylene, polypropylene, polypropylene with calcium carbonate, a polyimide foil with a conducting polyaniline layer containing a photointiator, polyvinyl chloride, or acrylonitrile butadiene styrene (ABS) or the like. The substrate can be comprised of a single substantially amorphous material or can comprise, for example, a composite of differentiated materials (for example a laminate construct) and typically also comprises an electrical insulator. Moreover the substrate may further comprise any suitable adhesive material on one side of the substrate for adhering the substrate to the storage medium.

At a step 608 an electronic circuit is generated, printed or attached onto the substrate using any number of techniques and material well known in the art, wherein a portion of the circuit is positioned (610) adjacent to the impression in the disc so that the impression alters the portion of the circuit to generate the secret code. In one embodiment as described above, the portion of the circuit comprises a memory array comprising a plurality of printed transistors. During the process the memory array is pressed against the impression, and the impression severs the links of some of the transistors comprising the memory array. This severing of links determines which transistors in the memory array will be turned ON or OFF which in turn determines the secret code that is generated when the ON/OFF states of the transistors are read from the memory array. In one efficient embodiment, the printed electronic circuit is pressed against the impression on the disc when the information is pressed on the disc as described above.

Turning to the printing of the electronic circuit elements comprising the printed electronic circuit, the printing of a transistor onto the substrate will be described, which can be generalized by those of ordinary skill in the art to print other electronic circuit elements such as, for instance, operational amplifiers, comparators, diodes, resistors, capacitors, inverters, and the like. The term “printing” will be understood to include such techniques as screen printing, offset printing, gravure printing, xerographic printing, flexography printing, inkjetting, micro-dispensing, spraying, stamping, and the like. Moreover, the term “ink” or “functional ink” is generally understood to comprise a suspension, solution or dispersant that is presented as a liquid, paste or powder (such as a toner powder). These inks are further comprised of metallic, organic, or inorganic materials having any of a variety of shapes (spherical, flakes, fibers, tubes) and sizes ranging, for example, from micron to nanometer.

With respect to a printed transistor, a first gate is printed on the substrate using a conductive ink of choice formed of a material such as, for instance, aluminum, magnesium, titanium, tantalum, manganese, calcium, zinc, etc. The gate may then be air dried and/or thermally cured to assist the gate in adhering to the substrate. A dielectric may then be printed over at least a substantial portion of the above-mentioned gate using, for example, an appropriate epoxy-based ink. In one approach, the dielectric comprises a laminate of two or more layers. Source and drain electrodes are then printed and cured using a conductive ink of choice formed of a material such as, for instance, copper, gold, silver, nickel, platinum, conductive polymer thick film, conductive polymer, carbon-based material, tungsten, etc. that will result in a contact as between itself and the semiconductor material later applied. A semiconductor or “active” material ink such as, but not limited to, an organic semiconductor material ink such as various formulations of polythiophene or a polythiophene-family material such as poly(3-hexylthiophene) or an inorganic semiconductor material ink containing SnO₂, SnO, ZnO, Ge, Si, GaAs, InAs, InP, SiC, CdSe, and various forms of carbon (including carbon nanotubes), is then printed to provide an area of semiconductor material that bridges a gap between the source electrode and the drain electrode.

Once the circuit elements (including the memory array) is coupled to the storage medium and the portion having the memory array is pressed against the impression in the disc material, a secret code is generated. The secret code may be used to protect the information in the disc from unauthorized copying.

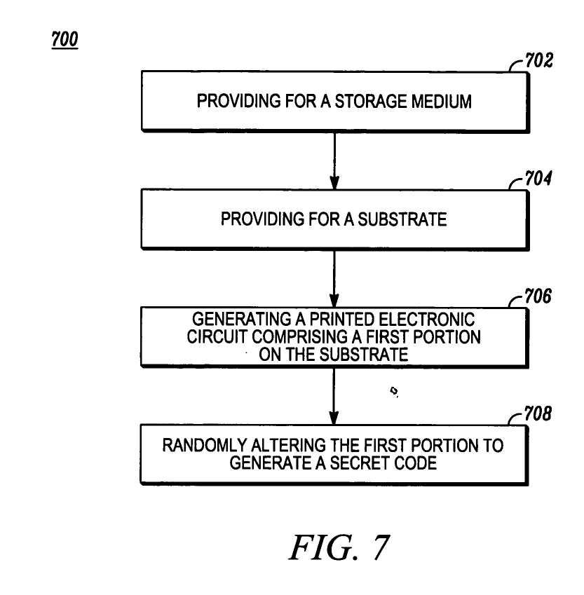

Turning now to FIG. 7, a flow diagram of a manufacturing method for producing a storage medium with a printed electronic circuit in accordance with an embodiment of the present invention is shown and generally indicated at 700. Process 700 comprises the steps of: providing (702) for a storage medium; providing (704) for a substrate; generating (706) a printed electronic circuit comprising a first portion on the substrate; and randomly altering (708) the first portion to generate a secret code. In accordance with this embodiment, the steps 702, 704 and 706 are essentially the same as steps 602, 606 and 608 described above. In step 708 a tool such as a laser may be used to carve an impression into the first portion (e.g., the memory array) to generate the secret code. In one embodiment, the laser uses a randomization algorithm to randomly alter the memory array. The randomization algorithm can be configured to randomly select a pattern for the impression. Moreover, as in the embodiment above, randomness may be introduced into the process based on the tool used to make or provide for the storage medium in that the tool may orient the disc in a random way before the electronic circuit is coupled thereto.

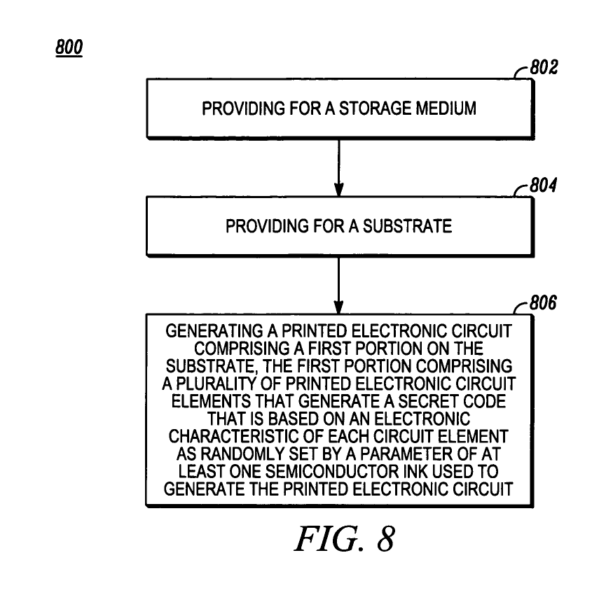

Turning now to FIG. 8, a flow diagram of a manufacturing method for producing a storage medium with a printed electronic circuit in accordance with an embodiment of the present invention is shown and generally indicated at 800. Process 800 comprises the steps of: providing (802) for a storage medium comprising a first material; providing (804) for a substrate; and generating (806) a printed electronic circuit comprising a first portion on the substrate, the first portion comprising a plurality of printed electronic circuit elements that generate a secret code, wherein the secret code is based on an electronic characteristic of each circuit element as randomly set by a parameter of at least one semiconductor ink used to generate the printed electronic circuit. Steps 802 and 804 are essentially the same as steps 602 and 606 described above. However, step 806 differs from the counterpart steps (608 and 706) described above in the manner in which the active semiconductor ink is deposited onto the circuit elements.

As stated above, the characteristics of a printed transistor can be varied depending on the amount of materials used to create the active part of the transistor. In addition, the characteristics of a printed transistor can be varied depending on the mobility of the semiconductor ink used to create the active portion of the transistor. These parameters can be used to generate the secret code. For instance in one embodiment, the a common transistor circuit is printed using a plurality of clear semiconductor inks each having a different mobility, where mobility is defined as Velocity/unit electric field, i.e., units of (cm/s)/(V/cm). Higher mobility of the active semiconductor layer allows for faster transfer of electrons from the source to the drain of a printed transistor. The printing tool can use a randomization algorithm to randomize which ink is used and how the ink is deposited. The randomization algorithm can further randomize the thickness of the active material deposited to further randomize the characteristics of the printed transistors. In this manner, transistors can be generated having different ON/OFF threshold voltages that generates a unique secret code based on the randomization process of depositing the semiconductor ink.

In a similar manner, instead of or in addition to the characteristics of a printed transistor being varied based on the randomness of the ink being applied, other circuit elements can have characteristics that are varied in the same manner. For example, the output of a comparator or operational amplifier (“op-amp”) can be uniquely modified by depositing the different semiconductor material for that specific op-amp/comparator. The op-amp/comparator can be used to generate the unique secret code. Also, a random frequency for an oscillator can be generated based on the random variation of deposition of semiconductor material as described above, which can be used to generate the unique secret code.

An advantage of the aforementioned embodiments is that the secret code cannot be readily ascertained from the printed electronic circuit due to the small size of the circuit. In addition other measurements may be implemented such as covering the printed electronic circuit with a blank label so that the circuit cannot be viewed even with a powerful microscope. The lifting of the label would thereby destroy the circuit rendering it useless for its intended functionality. Moreover, in the embodiment where the secret code is determined based on different semiconductor inks having different mobilities and/or different ink differences used to print the circuit elements, a visual inspection will not help in determining the electrical characteristics of the circuit elements in order to determine the secret code. This would enable only one “authorized” reader having the secret code to read the information contained on the disc.

Accordingly, when a disc, for example, is first placed in contact with a disc reader, the reader is configured to ask for the secret code. The printed electronic circuit is configured to read the secret code from the memory array and send it to the reader so that the reader is able to use the code to decrypt the information stored on the disc. In one embodiment, the secret code is a read-once code, wherein the printed electronic circuit will read and send the secret code to a reader only one time. Read-once can be implemented via a fuse, in a way that after reading the code, that specific reading path on the circuit is opened when the fuse is blown. As is done in encryption authentication methods, the reader can later send a challenge string to an authentication circuit which can then encrypt it and send the encrypted data back to the reader, which the reader can then verify that the encrypted data is correct, thus authenticating the circuit. An additional method can be a counter like the one used in automobile key fobs and can also be used as an authentication process. Thus, if the disc is copied, the memory array comprising the code cannot be copied, and without the secret code the copy is rendered useless.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Moreover in this document, relational terms such as first and second, top and bottom, and the like may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, “contains . . . a” does not, without more constraints, preclude the existence of additional identical elements in the process, method, article, or apparatus that comprises, has, includes, contains the element. The terms “a” and “an” are defined as one or more unless explicitly stated otherwise herein. The terms “substantially”, “essentially”, “approximately”, “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. The term “coupled” as used herein is defined as connected, although not necessarily directly and not necessarily mechanically. A device or structure that is “configured” in a certain way is configured in at least that way, but may also be configured in ways that are not listed.

What is claimed is:

1. Apparatus comprising:
a storage medium comprising a first material; and
a printed electronic circuit coupled to the storage medium, the printed electronic circuit comprising a first portion that includes a plurality of printed electronic circuit elements that generate a secret code, wherein the secret code is based on an electronic characteristic of each circuit element as randomly set by a parameter of at least one semiconductor ink used to generate the printed electronic circuit.

2. The apparatus of claim 1, wherein the storage medium is a disc storage medium.

3. The apparatus of claim 1, wherein the secret code is a read-once code that can be read by a reader device only once from the printed electronic circuit.

4. The apparatus of claim 1, wherein the first portion comprises a memory array including a plurality memory cells a portion of which have an electronic characteristic that is set by a parameter of at least one semiconductor ink to generate the secret code.

5. The apparatus of claim 4, wherein the plurality of memory cells comprises a plurality of printed transistors.

6. The apparatus of claim 1, wherein the printed electronic circuit is printed on a substrate having an adhesive, wherein the substrate and adhesive is pressed onto the storage medium.

7. The apparatus of claim 6, wherein the substrate comprises a second material selected from the group comprising: polyester, paper, plastic, acetate, polyethylene, polypropylene, polypropylene with calcium carbonate, a polyimide foil with a conducting polyaniline layer containing a photointiator, polyvinyl chloride, and acrylonitrile butadiene styrene.

8. The apparatus of claim 1, wherein the printed electronic circuit is printed directly on the first material.

9. The apparatus of claim 1, wherein the printed electronic circuit comprises a radio frequency identification circuit.

10. The apparatus of claim 1, wherein the first material comprises an antenna for operatively coupling the printed electronic circuit to a destination device that reads the secret code.

11. The apparatus of claim 1, wherein the printed electronic circuit is generated using a semiconductor ink.

12. A destination device comprising a first circuit that when operatively coupled to a source device further comprising a storage medium comprising a first material and a printed electronic circuit coupled to the storage medium, the printed electronic circuit comprising a first portion that includes a plurality of printed electronic circuit elements that generate a secret code, wherein the secret code is based on an electronic characteristic of each circuit element as randomly set by a parameter of at least one semiconductor ink used to generate the printed electronic circuit, the first circuit is operative to read the secret code from the printed electronic circuit.

13. The destination device of claim 12, wherein the destination device comprises a first antenna and the source device comprises a second antenna that are coupled using a wireless interface, for operatively coupling the destination and source devices.

14. The destination device of claim 12, wherein the first circuit and printed electronic circuit are directly physically connected, for operatively coupling the destination and source device.

15. A method for manufacturing apparatus comprising an embedded secret, the method comprising the steps of:
providing for a storage medium;
providing for a substrate; and
generating a printed electronic circuit comprising a first portion on the substrate, the first portion comprising a plurality of printed electronic circuit elements that generate a secret code, wherein the secret code is based on an electronic characteristic of each circuit element as randomly set by a parameter of at least one semiconductor ink used to generate the printed electronic circuit.

16. The method of claim 15, wherein the parameter of the at least one semiconductor ink is a mobility of each semiconductor ink used to generate the printed electronic circuit.

17. The method of claim 16, wherein an electronic characteristic of a first circuit element is randomly set by a first mobility of a first semiconductor ink used to print the first circuit and at least a second circuit element is randomly set by a second mobility of a second semiconductor ink used to print the second circuit, wherein the second mobility is different from the first mobility.

18. The method of claim 16, wherein the parameter is a thickness of the at least one semiconductor ink used to generate the printed electronic circuit.
